(19) United States
(12) Patent Application Publication
(10) Pub. No.: US 2012/0320642 A1
(43) Pub. Date: Dec. 20, 2012

(54) COMPOUND SEMICONDUCTOR DEVICE AND METHOD OF MANUFACTURING THE SAME

(75) Inventor: Kenji IMANISHI, Atsugi (JP)

(73) Assignee: FUJITSU LIMITED, Kawasaki-shi (JP)

(21) Appl. No.: 13/469,564

(22) Filed: May 11, 2012

(30) Foreign Application Priority Data
Jun. 16, 2011 (JP) 2011-134542

(51) Int. Cl. H02M 5/458; H01L 21/20; H03F 3/19; H01L 29/20

(52) U.S. Cl. 363/37; 257/76; 438/478; 257/615; 330/250; 257/E29.089; 257/E21.09

(57) ABSTRACT

A compound semiconductor device includes a substrate; and a compound semiconductor multilayer structure which is formed above the substrate and which contains compound semiconductors containing Group III elements, wherein the compound semiconductor multilayer structure has a thickness of 10 μm or less and a percentage of aluminum atoms is 50% or more of the number of atoms of the Group III elements.

### CROSS-REFERENCE TO RELATED APPLICATION(S)

This application is based upon and claims the benefit of priority of the prior Japanese Patent Application No. 2011-134542, filed on Jun. 16, 2011, the entire contents of which are incorporated herein by reference.

### FIELD

The embodiments discussed herein are related to a compound semiconductor device and a method of manufacturing the same.

### BACKGROUND

Nitride semiconductors have properties such as high saturated electron drift velocity and a wide band gap and therefore are being attempted to be used for high-voltage, high-power semiconductor devices. For example, GaN, which is a nitride semiconductor, has a band gap of 3.4 eV, which is greater than the band gap (1.1 eV) of Si and the band gap (1.4 eV) of GaAs, and also has high breakdown field strength. Therefore, GaN is a highly promising material for semiconductor devices for power supplies for obtaining high-voltage and high power.

A large number of reports have been made about semiconductor devices, such as field-effect transistors, containing nitride semiconductors and particularly about high electron mobility transistors (HEMTs). Among, for example, GaN-based HEMTs (GaN-HEMTs), an AlGaN/GaN-HEMT including an electron travel layer made of GaN and an electron supply layer made of AlGaN is attracting attention. In the AlGaN/GaN-HEMT, strain due to the difference in lattice constant between GaN and AlGaN is caused in AlGaN. A high-concentration of two-dimensional electron gas (2DEG) is obtained due to piezoelectric polarization induced thereby and the spontaneous polarization of AlGaN. Therefore, the AlGaN/GaN-HEMT is promising as a high-efficiency switching element, a high-voltage power device for electric vehicles, or the like

Since it is very difficult to produce a GaN single crystal, there is no large-size substrate for use in GaN semiconductor devices. Therefore, a GaN crystal layer is formed on a substrate of SIC, sapphire, Si, or the like by heteroepitaxial growth. In particular, a Si substrate having a large size and high quality may be produced at low cost. Therefore, in recent years, various attempts have been made to form GaN crystal layers on a Si substrate toward the practical application of GaN semiconductor devices.

A large voltage is used to operate a GaN semiconductor device. Therefore, in the case of using a Si substrate or the like, it is known that an electric field generated by an applied voltage passes through an active portion of a compound semiconductor multilayer structure to reach a portion of the Si substrate and therefore a dielectric breakdown occurs in the Si substrate. GaN crystal layers are excellent in dielectric breakdown resistance. Therefore, the dielectric breakdown of a substrate can probably be suppressed in such a manner that a GaN crystal layer included in a compound semiconductor multilayer structure disposed on the substrate is formed so as to have a large thickness.

However, in the case of using a Si substrate, there are large differences in lattice constant and thermal expansion coefficient between the Si substrate and a GaN crystal layer. Therefore, it is difficult to form the GaN crystal layer on the Si substrate; hence, there is a problem in that the dielectric breakdown of the Si substrate is not sufficiently suppressed. In particular, the differences in lattice constant and thermal expansion coefficient between the Si substrate and the GaN crystal layer are very large; hence, the GaN crystal layer is incapable of being thickly formed. Furthermore, as a substrate for growing a GaN crystal, the Si substrate has a smaller band gap and poorer insulation performance as compared with SiC substrates, sapphire substrates, and the like. The Si substrate usually has low resistivity. Therefore, conventional GaN semiconductor devices are incapable of ensuring the dielectric strength of Si substrates or the like at present. Japanese Laid-open Patent Publication No. 2010-499597 is an example of related art.

### SUMMARY

According to an aspect of the invention, a compound semiconductor device includes: a substrate; and a compound semiconductor multilayer structure which is formed above the substrate and which contains compound semiconductors containing Group III elements, wherein the compound semiconductor multilayer structure has a thickness of 10 μm or less and a percentage of aluminum atoms is 50% or more of the number of atoms of the Group III elements.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1C are schematic sectional views illustrating steps of a method of manufacturing an AlGaN/GaN-HEMT according to a first embodiment;

FIGS. 2A and 2B are schematic sectional views illustrating steps of the method of manufacturing the AlGaN/GaN-HEMT according to the first embodiment subsequently to FIG. 1;

FIGS. 3A and 3B are schematic sectional views illustrating steps of the method of manufacturing the AlGaN/GaN-HEMT according to the first embodiment subsequently to FIG. 2;

FIG. 4 is a schematic sectional view illustrating how a first buffer layer of a compound semiconductor multilayer structure is formed in the first embodiment;

FIG. 5 is a graph illustrating the relationship between the sheet resistance and thickness of a GaN layer in a compound semiconductor multilayer structure;

FIG. 6 is a schematic view illustrating the AlGaN/GaN-HEMT according to the first embodiment and the depthwise distribution of components of the compound semiconductor multilayer structure;

FIG. 7 is a graph illustrating results obtained by evaluating the dielectric strength of AlGaN/GaN-HEMTs.

FIG. 8 is a graph illustrating results obtained by evaluating pinch-off characteristics of AlGaN/GaN-HEMTs;

FIGS. 9A and 9B are graphs illustrating results obtained by evaluating the energy bands of AlGaN/GaN-HEMTs;

FIG. 10 is a graph illustrating results obtained by investigating the relationship between the thickness and dielectric strength of compound semiconductor multilayer structures including first buffer layers having different thicknesses;

FIGS. 11A and 11B are schematic sectional views illustrating main steps of a method of manufacturing an AlGaN/GaN-HEMT according to a second embodiment;

FIG. 12 is a schematic sectional view illustrating how a second buffer layer of a compound semiconductor multilayer structure is formed in the second embodiment;

FIG. 13 is a schematic view illustrating the AlGaN/GaN-HEMT according to the second embodiment and the depthwise distribution of components of the compound semiconductor multilayer structure;

FIG. 14 is a wiring diagram illustrating the schematic configuration of a power supply unit according to a third embodiment; and

FIG. 15 is a wiring diagram illustrating the schematic configuration of a high-frequency amplifier according to a fourth embodiment.

### DESCRIPTION OF EMBODIMENTS

Hereinafter, embodiments will be described in detail with reference to the attached drawings. In the embodiments, the configurations of compound semiconductor devices and methods of manufacturing the compound semiconductor devices are described.

In the drawings, the relative size and thickness of some members are not correctly illustrated for convenience of illustration.

### First Embodiment

This embodiment discloses an AlGaN/GaN-HEMT useful as a compound semiconductor device.

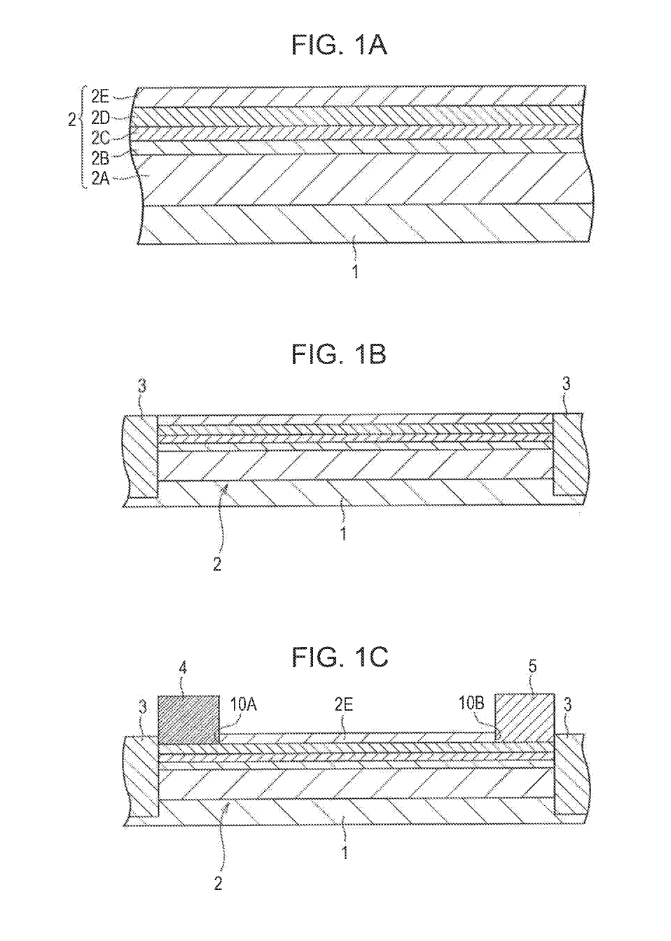

FIGS. 1A to 3B are schematic sectional views illustrating steps of a method of manufacturing the AlGaN/GaN-HEMT according to the first embodiment.

Various substrates such as SIC substrates, sapphire substrates, Si substrates, GaAs substrate, and GaN substrates can be used regardless of whether the substrates are electrically conductive, semi-insulating, or insulating. For example, SiC substrates, sapphire substrates, and Si substrates can be used herein because these substrates can be readily produced so as to have a large diameter and have excellent versatility. In this embodiment, the use of a Si substrate is exemplified because the Si substrate has excellent versatility and is low in production cost.

As illustrated in FIG. 1A, a compound semiconductor multilayer structure 2 is formed on a Si substrate 1.

The compound semiconductor multilayer structure 2 includes a first buffer layer 2A, a second buffer layer 2B, an electron travel layer 2C, an electron supply layer 2D, and a cap layer 2E. The first buffer layer 2A is made of AlN. The second buffer layer 2B is made of i-type AlGaN (i-AlGaN) unintentionally doped with an impurity. The electron travel layer 2C is made of GaN (i-GaN) unintentionally doped with an impurity. The electron supply layer 2D is made of n-AlGaN. The cap layer 2E is made of n-GaN.

In this embodiment, the compound semiconductor multilayer structure 2 has a thickness of about 10 μm or less and the percentage of aluminum atoms is 50% or more of the number of Group III element atoms contained therein. The compound semiconductor multilayer structure 2 is made of a Group III-V semiconductor containing a Group V element which is nitrogen (N) and Group III elements which are gallium (Ga) and aluminum (Al). N may be chemically bonded to all of the Group III elements. Thus, the percentage of N atoms is theoretically 50% of the number of all atoms in the compound semiconductor multilayer structure 2. The percentage of Al atoms is 25% or more of the number of all atoms, that is, the percentage of the Al atoms is 50% or more of the number of all atoms of the Group III elements. In other words, this means that the number of Al—N bonds is 50% or more of the number of all chemical bonds (Ga—N bonds and Al—N bonds) of the Group III element to N.

The first buffer layer 2A has a function of forming growth nuclei at the lowermost portion thereof, a function of buffering the difference in lattice constant between Si in the Si substrate 1 and AlGaN in the second buffer layer 2B, and a function of resisting dielectric breakdown as described below. The second buffer layer 2B has a function of buffering the difference in lattice constant between AlN in the first buffer layer 2A and GaN in the electron travel layer 2C.

In the AlGaN/GaN-HEMT, a two-dimensional electron gas (2DEG) is generated near the interface between the electron travel layer 2C and the electron supply layer 2D during the operation thereof. The 2DEG is produced due to the difference in spontaneous polarization between a compound semiconductor (herein GaN) in the electron travel layer 2C and a compound semiconductor (herein AlGaN) in the electron supply layer 2D and the difference in piezoelectric polarization therebetween.

In order to form the compound semiconductor multilayer structure 2, compound semiconductors below are deposited on the Si substrate 1 by a crystal growth process, for example, a metal-organic chemical vapor deposition (MOCVD) process. Molecular beam epitaxy (MBE) or the like may be used instead of the MOCVD process.

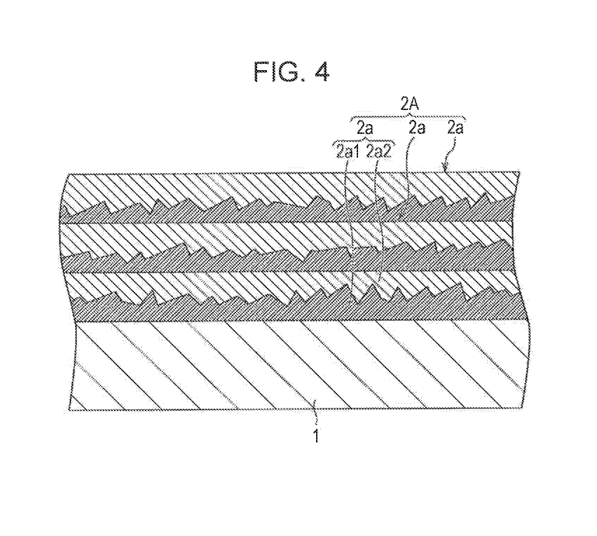

AlN is thickly deposited on the Si substrate 1 to a thickness of about 1,000 nm, whereby the first buffer layer 2A is formed. This layer is illustrated in FIGS. 1A and 4.

In particular, a gas mixture of a trimethyl aluminum (TMAI) gas and an ammonia (NH₃) gas is used as a source gas. The ratio of NH₃ to TMAI in the gas mixture, that is, the V/III ratio is set to 10,000 or more, for example, 20,000. AlN is deposited to a thickness of, for example, about 50 nm, whereby a lower AlN layer 2a1 is formed. Since the lower AlN layer 2a1 is formed under such a condition that the ratio of NH₃ to TMAl, that is, the V/III ratio is large as described above, AlN forms islands on a growth surface and therefore the lower AlN layer 2a1 has an hubbly surface.

Next, the ratio of NH₃ to TMAl, that is, the V/III ratio is set to 2.0 or less, for example, 1.0, and AlN is deposited on the lower AlN layer 2a1 to a thickness of, for example, about 100 nm, whereby an upper AlN layer 2a2 is formed. Since the upper AlN layer 2a2 is formed under such a condition that the ratio of NH₃ to TMAl, that is, the V/III ratio is very small as described above, the migration of Al atoms and N atoms on a growth surface is promoted and therefore the upper AlN layer 2a2 has a flat surface. The upper AlN layer 2a2 is deposited over the lower AlN layer 2a1 as described above, whereby an AlN layer 2a with a flat surface is formed.

A step of forming the AlN layer 2a is repeated several times, for example, seven times, whereby several AlN layers 2a (herein seven AlN layers 2a) are stacked to form the first buffer layer 2A. The first buffer layer 2A has a large thickness of about 1,000 nm. FIG. 4 illustrates three of the stacked AlN layers 2a. One of the upper AlN layers 2a2 is uppermost and therefore the first buffer layer 2A has a flat surface. For example, TEM analysis confirms that the AlN layers 2a making up the first buffer layer 2A each have a multilayer structure consisting of the lower AlN layer 2a1, which has the hubbly surface, and the upper AlN layer 2a2, which has the flat surface.

In order to ensure the dielectric strength of the Si substrate 1 by raising the content of Al in the compound semiconductor multilayer structure 2, the first buffer layer 2A, which is placed between the Si substrate 1 and the electron travel layer 2C and is made of AlN, is preferably thickly formed. However, AlN is not lattice-matched to substrate materials such as Si and SiC. Therefore, if the first buffer layer 2A is thickly formed on the Si substrate 1, a large stress is caused in the first buffer layer 2A because of lattice mismatch. Therefore, it is difficult to thickly form the first buffer layer 2A.

In this embodiment, the lower AlN layers 2a1 and the upper AlN layers 2a2 have island-shaped growth surfaces and flat growth surfaces, respectively, and are alternately stacked, whereby the first buffer layer 2A is formed. Since the first buffer layer 2A, which is substantially thick, is formed by alternately stacking the lower and upper AlN layers 2a1 and 2a2, which are different in surface morphology and are relatively thin, as described above, the stress in the first buffer layer 2A is relieved. It has been found that a thick AlN crystal can be stably formed even if there is a large lattice mismatch between a substrate material and AlN.

In order to alternately deposit the lower AlN layers 2a1, which have the island-shaped growth surfaces, and the upper AlN layers 2a2, which have the flat growth surfaces, a method other than a method of varying the WM ratio may be used. For example, a method of varying the growth temperature of AlN can be used. In particular, the lower AlN layers 2a1 are grown at a temperature of, for example, about 850° C. to 950° C. and the upper AlN layers 2a2 may be grown at a temperature higher than the growth temperature of the lower AlN layers 2a1, that is, a temperature of, for example, about 1,000° C. to 1,150° C.

The upper surface of each lower AlN layer 2a1 can be made hubbly in such a manner that after the lower AlN layer 2a1 is formed, the supply of the source gas is stopped and the lower AlN layer 2a1 is heated to a temperature of about 1,100° C. to 1,200° C. and is then left at this temperature.

Subsequently to the formation of the first buffer layer 2A, the second buffer layer 2B, the electron travel layer 2C, the electron supply layer 2D, and the cap layer 2E are deposited on the first buffer layer 2A in that order.

In particular, the second buffer layer 2B is formed in such a manner that i-AlGaN (for example, Al_{0.50}Ga_{0.50}N) is deposited on the first buffer layer 2A, which has a flat surface, to a thickness of about 200 nm. The electron travel layer 2C is formed in such a manner that i-GaN is thinly deposited to a thickness of, for example, 250 nm or less (herein about 230 nm). The electron supply layer 2D is formed in such a manner that n-AlGaN (for example, Al_{0.25}Ga_{0.75}N) is deposited to a thickness of about 30 nm. The cap layer 2E is formed in such a manner that n-GaN is deposited to a thickness of about 10 nm.

The compound semiconductor multilayer structure 2 is formed on the Si substrate 1 as described above.

As for conditions for depositing AlGaN and GaN, a gas mixture of a TMAl gas, a trimethyl gallium (TMGa) gas, and an NH₃ gas is used as a source gas. The supply and flow rate of the TMAl gas, which is an Al source, and those of the TMGa gas, which is a Ga source, are appropriately set depending on a compound semiconductor layer to be grown. The flow rate of the NH₃ gas, which is a common source, is about 10 cc/min to 100 L/min. The deposition pressure is about 50 Torr to 300 Torr. The deposition temperature is about 1,000° C. to 1,200° C.

In the case of depositing GaN and AlGaN in the form of an n-type, for example, a SiH₄ gas containing Si, which acts as an n-type impurity, is added to the source gas, whereby GaN and AlGaN are doped with Si. The doping concentration of Si is about 1×10¹⁸ cm⁻³ to 1×10²⁰ cm⁻³, for example, about 5×10¹⁸ cm⁻³.

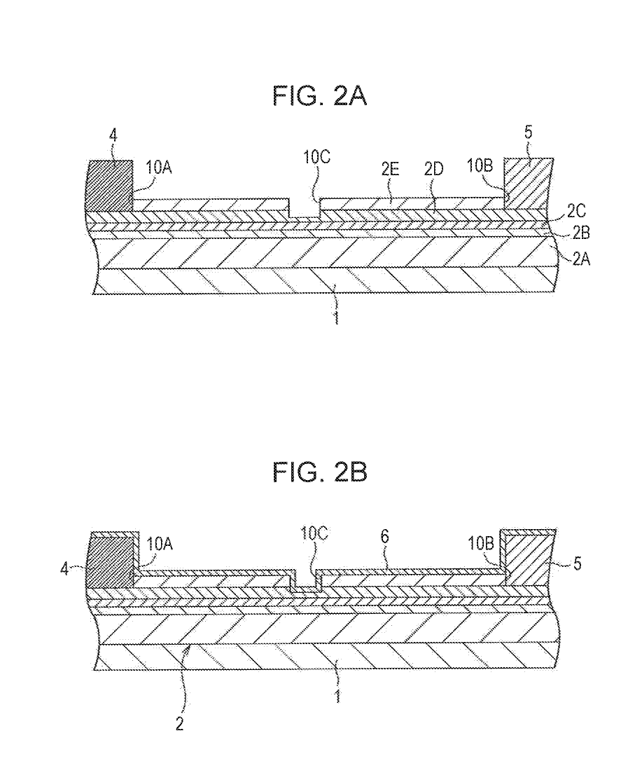

As illustrated in FIG. 1B, an isolation structure 3 is formed. In FIG. 2A and subsequent figures, the isolation structure 3 is not illustrated.

In particular, an isolation region of the compound semiconductor multilayer structure 2 is implanted with for example, argon (Ar). This allows the isolation structure 3 to be formed in the compound semiconductor multilayer structure 2 and a surface portion of the Si substrate 1. The isolation structure 3 defines an active region on the compound semiconductor multilayer structure 2. The isolation structure 3 may have a depth sufficient to electrically isolate elements and may extend to an intermediate portion of the compound semiconductor multilayer structure 2 or through the compound semiconductor multilayer structure 2.

For example, a shallow trench isolation (STI) process may be used to form the isolation structure 3 instead of the above implantation process. In this case, for example, a chlorine-containing etching gas may be used to dry-etch the compound semiconductor multilayer structure 2.

As illustrated in FIG. 1C, a source electrode 4 and a drain electrode 5 are formed.

In particular, electrode recesses 10A and 10B are formed at sites (planned electrode sites) at which the source electrode 4 and the drain electrode 5 are planned to be formed and which are arranged on the compound semiconductor multilayer structure 2.

A resist is applied onto the compound semiconductor multilayer structure 2. The resist is processed by lithography, whereby openings are formed in the resist such that surface portions of the compound semiconductor multilayer structure 2 that correspond to the planned electrode sites are exposed through the openings. This allows a resist mask having the openings to be formed.

Portions of the cap layer 2E that correspond to the planned electrode sites are removed by dry etching using the resist mask such that a surface of the electron supply layer 2D is exposed. This allows the electrode recesses 10A and 10B to be formed such that surface portions of the electron supply layer 2D that correspond to the planned electrode sites are exposed. As for etching conditions, etching gases used are an inert gas such as Ar and a chlorine-based gas such as Cl₂; the flow rate of Cl₂ is, for example, 30 cc/min; the pressure thereof is 2 Pa; and the input RF power is 20 W. The electrode recesses 10A and 10B may be formed by etching so as to extend to an intermediate portion of the cap layer 2E or so as to extend to or through the electron supply layer 2D.

The resist mask is removed by ashing or the like.

A resist mask for forming the source electrode 4 and the drain electrode 5 is formed. For example, a two-layer resist, suitable for a lift-off process, having a visor structure is used herein. The two-layer resist is applied onto the compound semiconductor multilayer structure 2 and openings for exposing the electrode recesses 10A and 10B are then formed therein. This allows the resist mask having these openings to be formed.

For example, Ta and/or Al, which is an electrode material, is deposited over the resist mask having the openings for exposing the electrode recesses 10A and 10B by, for example, a vapor deposition process. The thickness of a layer of Ta is about 20 nm. The thickness of a layer of Al is about 200 nm. This resist mask and Ta and/or Al deposited thereon are removed by the lift-off process. Subsequently, the Si substrate 1 is heat-treated at a temperature of about 400° C. to 1,000° C., for example, about 600° C. in a nitrogen atmosphere, whereby remaining portions of Ta and/or Al are brought into ohmic contact with the electron supply layer 2D. If ohmic contacts between the electron supply layer 2D and the remaining portions of Ta and/or Al are obtained, heat treatment does not have to be done in some cases. Through the above operations, the electrode recesses 10A and 10B are filled with portions of the electrode material and thereby the source electrode 4 and the drain electrode 5 are formed.

As illustrated in FIG. 2A, an electrode recess 10C for forming a gate electrode 7 is formed in the compound semiconductor multilayer structure 2.

In particular, a resist is applied onto the compound semiconductor multilayer structure 2. This resist is processed by lithography, whereby an opening is formed in the resist such that a surface portion of the compound semiconductor multilayer structure 2 that corresponds to a site (planned electrode site) at which the gate electrode 7 is planned to be formed is exposed through the opening. This allows a resist mask having the opening to be formed.

A portion of the cap layer 2E that corresponds to the planned electrode site and a portion of the electron supply layer 2D that corresponds to the planned electrode site are removed by dry etching using this resist mask. This results in that the electrode recess 10C is formed so as to extend through the cap layer 2E to a portion of the electron supply layer 2D. As for etching conditions, etching gases used are an inert gas such as Ar and a chlorine-based gas such as Cl₂; the flow rate of Cl₂ is, for example, 30 cc/min; the pressure thereof is 2 Pa; and the input RF power is 20 W. The electrode recess 10C may be formed by etching so as to extend to an intermediate portion or deeper portion of the electron supply layer 2D.

This resist mask is removed by ashing or the like.

As illustrated in FIG. 2B, a gate insulating layer 6 is formed.

In particular, for example, Al₂O₃, which is an insulating material, is deposited over the compound semiconductor multilayer structure 2 so as to cover the wall of the electrode recess 10C. Al₂O₃ is deposited to a thickness of about 2 nm to 200 nm (herein about 10 nm) by an atomic layer deposition (ALD) process. This allows the gate insulating layer 6 to be formed.

For example, a plasma-enhanced chemical vapor deposition (PECVD) process, a sputtering process, or the like may be used to deposit Al₂O₃ instead of the ALD process. Furthermore, a nitride or oxynitride of Al may be used instead of Al₂O₃. Alternatively, the gate insulating layer 6 may be formed in such a manner that some selected from oxides, nitrides, and oxynitrides of Si, Hf, Zr, Ti, Ta, and W are deposited to form a multilayer structure.

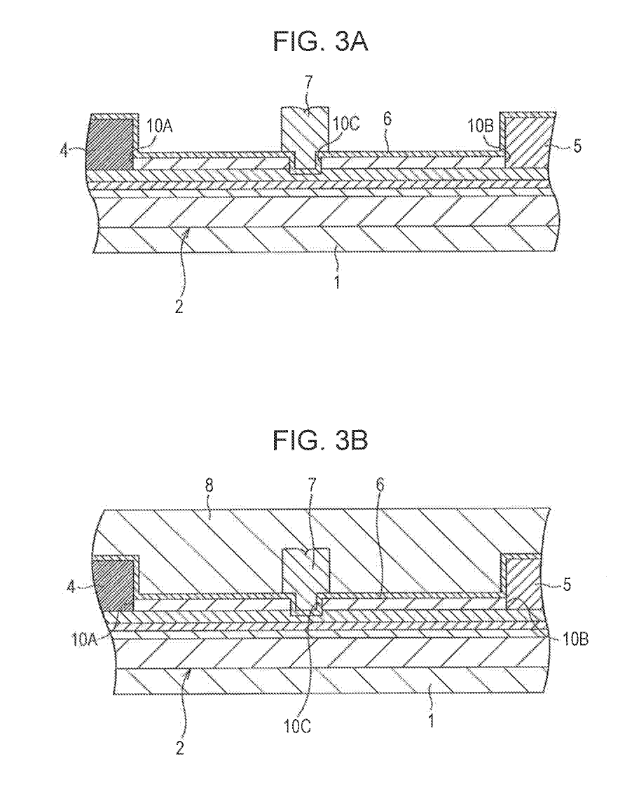

As illustrated in FIG. 3A, the gate electrode 7 is formed.

In particular, a resist mask for forming the gate electrode 7 is formed. For example, a two-layer resist, suitable for a vapor deposition process and a lift-off process, having a visor structure is used herein. The two-layer resist is applied onto the gate insulating layer 6 and an opening for partly exposing the electrode recess 10C in the gate insulating layer 6 is then formed therein. This allows the resist mask having the opening to be formed.

For example, Ni and/or Au, which is an electrode material, is deposited over the resist mask having the opening for partly exposing the electrode recess 10C in the gate insulating layer 6 by, for example, the vapor deposition process. The thickness of a layer of Ni is about 30 nm. The thickness of a layer of Au is about 400 nm. This resist mask and Ni and/or Au deposited thereon are removed by the lift-off process. Through the above operations, the electrode recess 10C covered by the gate insulating layer 6 is filled with a portion of the electrode material and thereby the gate electrode 7 is formed.

The electrode recess 10C may be formed closer to the source electrode 4 than the drain electrode 5 such that the gate electrode 7 is located close to the source electrode 4.

As illustrated in FIG. 3B, a passivation layer 8 is formed.

In particular, for example, silicon nitride is deposited over the source electrode 4, the drain electrode 5, and the gate electrode 7 by, for example, a PECVD process or the like. This allows the passivation layer 8 to be formed.

Thereafter, wiring lines connecting the source electrode 4, the drain electrode 5, and the gate electrode 7 are formed; a protective layer is formed thereover; and connection electrodes exposed at the top are formed. Through these steps, the AlGaN/GaN-HEMT according to this embodiment is formed.

In this embodiment, the AlGaN/GaN-HEMT includes the gate insulating layer 6 as exemplified above and therefore is of a MIS type. The AlGaN/GaN-HEMT may be of a Schottky type, that is, the gate electrode 7 may be in direct contact with the compound semiconductor multilayer structure 2 without forming the gate insulating layer 6.

A gate-recess structure in which the gate electrode 7 is placed in the electrode recess 10C does not have to be used. That is, the gate insulating layer 6 and the gate electrode 7 may be formed on the compound semiconductor multilayer structure 2 in that order or the gate electrode 7 may be formed directly on the compound semiconductor multilayer structure 2 without forming any recess in the compound semiconductor multilayer structure 2.

AlN has a lattice constant between those of Si and GaN and a thermal expansion coefficient between those of Si and GaN. AlN has a dielectric breakdown voltage of about 11.7×10⁶ V/cm and GaN has a dielectric breakdown voltage of about 3.3×10⁶ V/cm, that is, the dielectric breakdown voltage of AlN is three times greater than that of GaN. Therefore, AlN is a material having excellent dielectric breakdown resistance. Thus, the dielectric breakdown of the Si substrate 1 can probably be suppressed during the application of high voltage in such a manner that the percentage (the percentage of the number of Al—N chemical bonds) of Al atoms in the compound semiconductor multilayer structure 2 is increased and a thick layer of AlN (or a AlN-containing material) is formed under the electron travel layer 2C.

The thickness of the compound semiconductor multilayer structure 2 is increased by forming a thick layer of AlN (or a AlN-containing material). However, when the compound semiconductor multilayer structure 2 has a very large thickness, that is, a thickness of, for example, more than 10 μm, it takes a very long time to grow a compound semiconductor. This is not practical for manufacturing processes. When the compound semiconductor multilayer structure 2 has a thickness of more than 10 μm, it is unavoidable that the Si substrate 1 is negatively affected (warped or cracked).

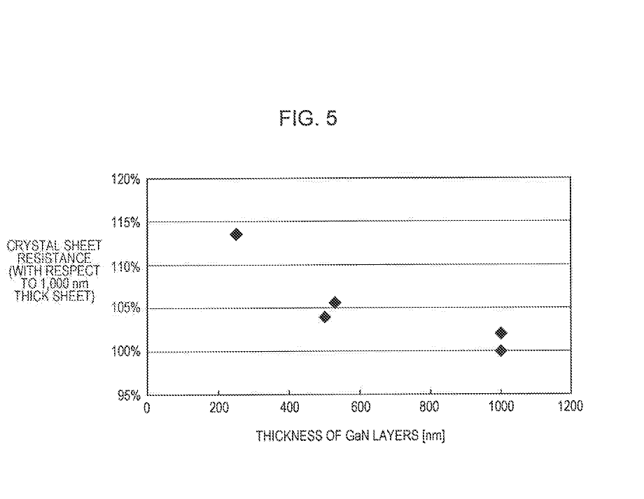

GaN is excellent in crystallinity; hence, in a conventional compound semiconductor multilayer structure, an electron travel layer has been formed by growing a thick layer of GaN. However, it has become clear that large increases in device properties are not achieved by forming such a thick layer of GaN. As illustrated in FIG. 5, the reduction in sheet resistance is small, less than 20% at most, and the mobility is not significantly increased even though the thickness of a GaN layer in a compound semiconductor multilayer structure is increased from about 200 nm to 1,000 nm. Thus, the desired mobility can be maintained even if the percentage (the percentage of Ga—N chemical bonds) of Ga atoms in this compound semiconductor multilayer structure is reduced and a relatively thin layer of GaN is formed.

This embodiment focuses the compound semiconductor multilayer structure 2 and properties of AlN and GaN contained therein. Under the restriction that the thickness of the compound semiconductor multilayer structure 2 is about 10 atm or less, the percentage of AlN in the compound semiconductor multilayer structure 2 is set to be large and the content of GaN therein is set to be small because AlN contributes to the increase in dielectric breakdown resistance of the compound semiconductor multilayer structure 2. In particular, the compound semiconductor multilayer structure 2 is formed such that the percentage of Al atoms is 25% or more of the number of all atoms contained in the compound semiconductor multilayer structure 2, that is, the percentage of the Al atoms is 50% or more of the number of all atoms of the Group III elements (in this case, the percentage of Ga atoms is 50% or less of the number of the all atoms of the Group III elements). In this embodiment, the first buffer layer 2A, which is made of AlN, is formed between the Si substrate 1 and the electron travel layer 2C so as to have a large thickness of, for example, about 1,000 nm. In contrast, the electron travel layer 2C is preferably formed so as to have a small thickness of, for example, about 500 nm or less, and more preferably about 250 nm or less. This allows the requirement for the percentage of the Al atoms to be achieved.

That is, the presence of the first buffer layer 2A, which is thick, allows the compound semiconductor multilayer structure 2 to have an increased AlN content and increased dielectric breakdown resistance and the presence of the electron travel layer 2C, which is thin, allows the compound semiconductor multilayer structure 2 to have a reduced GaN content and reduces the difference in lattice constant between GaN and the Si substrate 1. This is capable of securely suppressing the dielectric breakdown of the Si substrate 1 without warping or cracking the Si substrate 1.

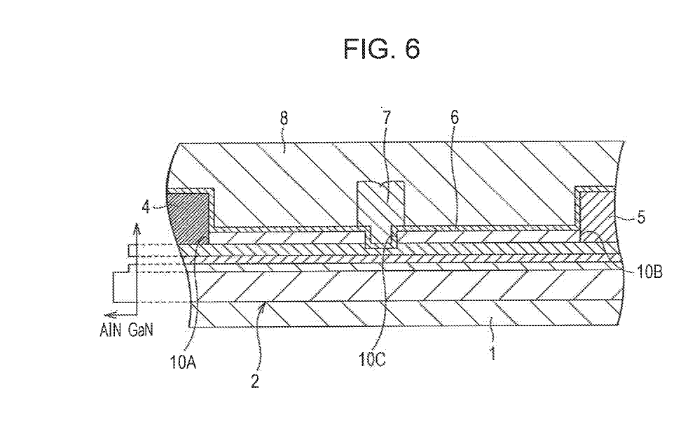

In particular, in the compound semiconductor multilayer structure 2, the first buffer layer 2A, which is made of AlN, is formed so as to have a large thickness of about 1,000 nm and the electron travel layer 2C, which is made of GaN, is formed so as to have a small thickness of about 100 nm as illustrated in FIG. 6, which includes a depthwise distribution map of components that is attached to the left side of FIG. 3B. This allows the percentage of the Al atoms to be 25% or more of the number of all atoms in the compound semiconductor multilayer structure 2.

### EXPERIMENTS

Experiments carried out to compare the AlGaN/GaN-HEMT according to this embodiment with AlGaN/GaN-HEMTs of comparative examples are described below.

### Experiment 1

In Experiment 1, AlGaN/GaN-HEMTs were evaluated for dielectric strength. Herein, the AlGaN/GaN-HEMT according to the first embodiment was referred to as an example and a conventional AlGaN/GaN-HEMT was referred to as a comparative example. A compound semiconductor multilayer structure of the comparative example was formed by depositing a first buffer layer, a second buffer layer, an electron travel layer, an electron supply layer, and a cap layer in that order as described below. The first buffer layer was formed by setting the ratio of NH₃ to TMAl, that is, the ratio to about 3,000 so as to have a thickness of about 100 nm. The first buffer layer was made of AlN. The second buffer layer was formed on the first buffer layer so as to have a thickness of about 200 nm. The second buffer layer was made of i-AlGaN. The electron travel layer was formed on the second buffer layer so as to have a large thickness (herein a thickness of about 1,000 nm). The electron travel layer was made of i-GaN. The electron supply layer and the cap layer were formed on the electron travel layer in that order in substantially the same manner as that described in this embodiment. The electron supply layer was made of n-AlGaN and had a thickness of about 30 nm. The cap layer was made of n-GaN and had a thickness of about 10 nm.

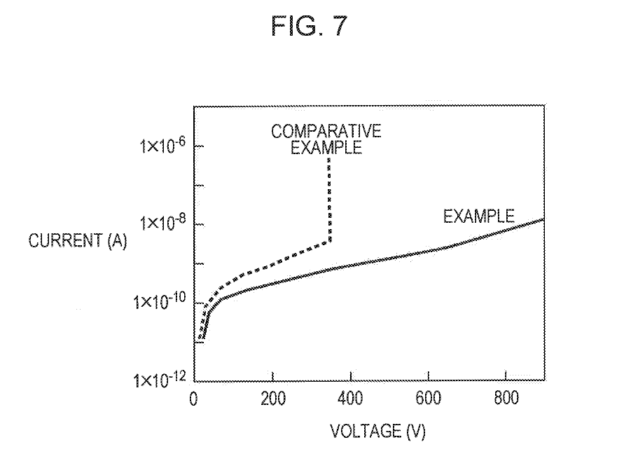

A drain electrode was formed on the front surface side and another electrode was formed on the back surface of a Si substrate. The current flowing through the drain electrode was measured in such a manner that the voltage applied to the drain electrode was gradually increased. Experiment results are illustrated in FIG. 7. The horizontal axis of FIG. 7 represents the voltage applied to the drain electrode and the vertical axis thereof represents the current flowing through the drain electrode.

In the comparative example, dielectric breakdown was observed at a voltage of more than about 350 V. In contrast, in the example, no dielectric breakdown was observed at a voltage of 900 V, which was the limit of the voltage applied to a measurement system. This demonstrates that the AlGaN/GaN-HEMT according to this embodiment has dielectric breakdown resistance that is significantly more excellent than that of the comparative example.

### Experiment 2

AlGaN/GaN-HEMTs were evaluated for pinch-off characteristics. In Experiment 2, the AlGaN/GaN-HEMT according to this embodiment was referred to as an example and a conventional AlGaN/GaN-HEMT similar to that described in Experiment 1 was referred to as a comparative example.

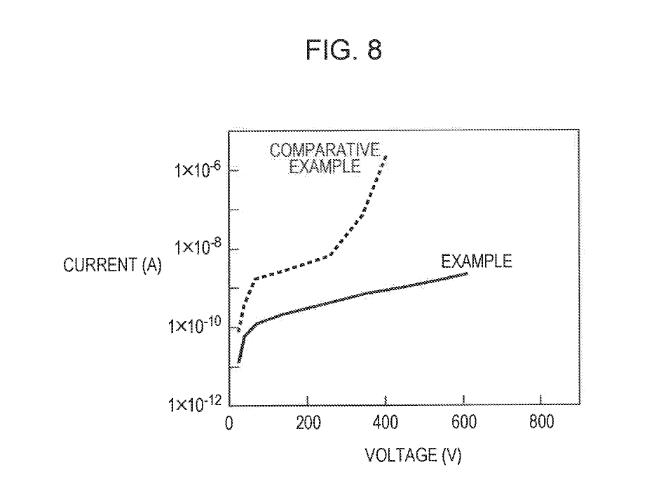

A source electrode was grounded and −10 V was applied to a gate electrode. In this state, a drain electrode was swept 0 V to +300 V. Experiment results are illustrated in FIG. 8. The horizontal axis of FIG. 8 represents the drain voltage and the vertical axis thereof represents the drain current.

In the comparative example, the increase of the drain current was observed at a drain voltage of about 100 V. This is probably due to one or both of a phenomenon in which the drain current flows along a depletion layer extending in an electron travel layer and a phenomenon in which impact ionization occurs in a deep portion of the electron travel layer.

In contrast, in the example, a very small drain current of less than 1×10⁻⁹ A flows at a drain voltage of 300 V and the drain current is blocked by a gate depletion layer. In the example, the increase of a current is suppressed probably because the pathway of a current is limited by a first buffer layer which is present under the electron travel layer and in which impact ionization is unlikely to occur. This demonstrates that the AlGaN/GaN-HEMT according to this embodiment has pinch-off characteristics that are significantly more excellent than those of the comparative example and also has a small leakage current when the AlGaN/GaN-HEMT according to this embodiment is pinched off by the gate voltage.

### Experiment 3

AlGaN/GaN-HEMTs were investigated for energy band. In Experiment 3, the AlGaN/GaN-HEMT according to this embodiment was referred to as an example and a conventional AlGaN/GaN-HEMT similar to that described in Experiment 1 was referred to as a comparative example.

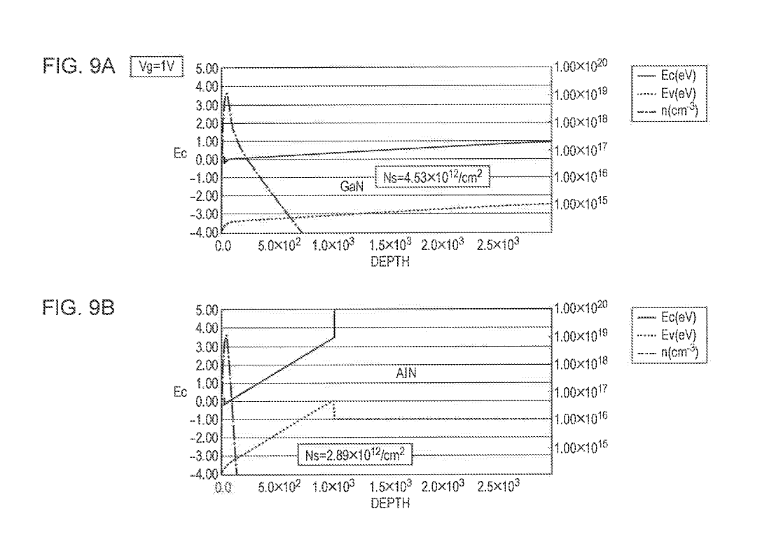

Results of the comparative example are illustrated in FIG. 9A and results of the example are illustrated in FIG. 9B. The horizontal axis of each of FIGS. 9A and 9B represents the depth of a portion of an electron travel layer from the interface between the electron travel layer and an electron supply layer and the vertical axis thereof represents the electron concentration thereof. In the comparative example, a 2DEG has a relatively large concentration distribution extending from the interface between the electron travel layer and the electron supply layer in a depth direction and the concentration of the 2DEG is large, 4.53×10¹² cm⁻². In contrast, in the example, a 2DEG has substantially no concentration distribution in a depth direction and is concentrated near the interface between the electron travel layer and the electron supply layer and the concentration of the 2DEG is small, 2.89×10¹² cm⁻². The AlGaN/GaN-HEMT according to this embodiment has a stronger piezoelectric effect as compared with the comparative example and the energy band is fixed by the piezoelectric effect. Therefore, the gate voltage to obtain a 2DEG with the same concentration as that of the comparative example is positive, which is suitable for normally off operation.

### Experiment 4

In this embodiment, the thickness of the first buffer layer 2A is determined in relation to the thickness of the compound semiconductor multilayer structure 2 in consideration of the impact on the Si substrate 1 and the dielectric strength desired for devices such that the percentage of Al atoms in the compound semiconductor multilayer structure 2 is within the above range. In this embodiment, the electron supply layer 2D and the cap layer 2E have a smaller thickness as compared with the other layers of the compound semiconductor multilayer structure 2 and therefore the change in thickness of the electron supply layer 2D and the cap layer 2E hardly contributes to the change in the percentage of the number of atoms of a Group III element. The second buffer layer 2B is used without being changed in thickness. Therefore, in the compound semiconductor multilayer structure 2, those greatly contributing to the change in the percentage of the number of the Group III element atoms through the change in thickness thereof are substantially two layers: the first buffer layer 2A and the electron travel layer 2C. Thus, determining the thickness of the first buffer layer 2A in relation to the thickness of the compound semiconductor multilayer structure 2 is substantially synonymous with determining the thickness of the first buffer layer 2A in relation to the thickness of the electron travel layer 2C.

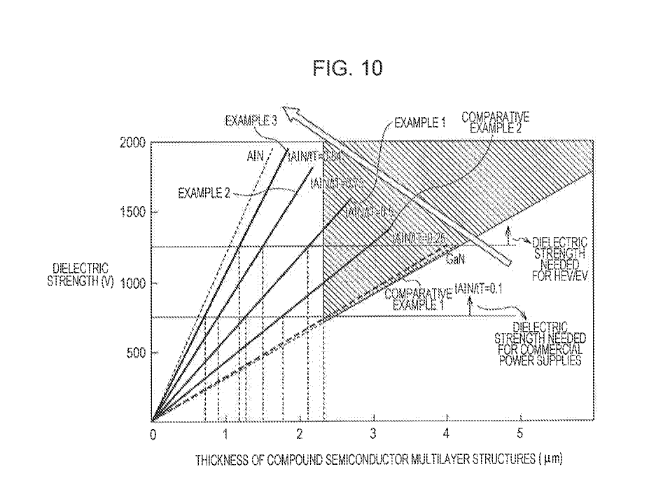

In Experiment 4, compound semiconductor multilayer structures including first buffer layers having different thicknesses were investigated for the relationship between thickness and dielectric strength. Experiment results are illustrated in FIG. 10. The tAlN/tT ratio was varied, wherein tT is the thickness (μm) of each compound semiconductor multilayer structure and tAlN is the thickness (μm) of a corresponding one of the first buffer layers, which are made of AlN. The larger the ratio tAlN/tT is (the closer to 1 the ratio tAlN/tT is), the thicker the first buffer layers are and the thinner electron travel layers are.

A conventional AlGaN/GaN-HEMT, similar to that described in Experiment 1, having a tAlN/tT ratio of 0.1 was referred to as Comparative Example 1 and one having a tAlN/tT ratio of 0.25 was referred to as Comparative Example 2. An AlGaN/GaN-HEMT having a tAlN/tT ratio of 0.51 was referred to as Example 1, an AlGaN/GaN-HEMT having a tAlN/tT ratio of 0.75 was referred to as Example 2, and an AlGaN/GaN-HEMT having a tAlN/tT ratio of 0.84 was referred to as Example 3, that is, these AlGaN/GaN-HEMTs were examples of this embodiment and contained Al atoms of which the number was within a range satisfying the above percentage. The AlGaN/GaN-HEMT of Example 2 having a tAlN/tT ratio of 0.75 included, for example, a compound semiconductor multilayer structure including layers substantially equal in thickness to those described in this embodiment. The AlGaN/GaN-HEMT of Example 3 having a tAlN/tT ratio of 0.84 included, for example, a compound semiconductor multilayer structure including a first buffer layer with a thickness of about 1,500 nm, an electron travel layer with a thickness of about 50 nm, and other layers substantially equal in thickness to those described in this embodiment.

The following conditions are added in FIG. 10: 750 V or more, which is the dielectric strength desired for commercial power supplies, and 1,200 V or more, which is the dielectric strength desired for power supplies for hybrid electric vehicles (HEVs)/electric vehicles (EVs). These are referred to as Conditions 1 and 2. Furthermore, the following condition is added in FIG. 10: about 2.3 μm, which is the upper limit of the thickness of a compound semiconductor multilayer structure capable of securely excluding a range causing a substrate to be warped or cracked. This is referred to as Condition 3.

As illustrated in FIG. 10, Examples 1 to 3 exhibit more excellent dielectric strength as compared with Comparative Examples 1 and 2. This demonstrates that the dielectric strength increases with an increase in tAlN/tT as indicated by an arrow in FIG. 10.

In Comparative Example 1, none of Condition 1 (Condition 2) and Condition 3 can be satisfied.

In Comparative Example 2, in order to satisfy both Condition 1 and Condition 3, the compound semiconductor multilayer structure thereof may have a thickness of about 1.8 μm to 2.3 μm. However, none of Condition 2 and Condition 3 can be satisfied.

In Example 1, in order to satisfy both Condition 1 and Condition 3, the compound semiconductor multilayer structure thereof may have a thickness of about 1.3 μm to 2.3 μm. In order to satisfy both Condition 2 and Condition 3, the compound semiconductor multilayer structure thereof may have a thickness of about 2.1 μm to 2.3 μm.

In Example 2, in order to satisfy both Condition 1 and Condition 3, the compound semiconductor multilayer structure thereof may have a thickness of about 0.9 μm to 2.3 μm. In order to satisfy both Condition 2 and Condition 3, the compound semiconductor multilayer structure thereof may have a thickness of about 1.5 μm to 2.3 μm.

In Example 3, in order to satisfy both Condition 1 and Condition 3, the compound semiconductor multilayer structure thereof may have a thickness of about 0.7 μm to 2.3 μm. In order to satisfy both Condition 2 and Condition 3, the compound semiconductor multilayer structure thereof may have a thickness of about 1.2 μm to 2.3 μm.

From the above, when tAlN/tT 0.51, results below are obtained.

When a compound semiconductor multilayer structure has a thickness of about 1.3 μm to 2.3 μm, the dielectric breakdown of a Si substrate is securely suppressed and dielectric strength specifications for commercial power supplies can be satisfied without causing the Si substrate to be warped or cracked.

When a compound semiconductor multilayer structure has a thickness of about 2.1 μm to 2.3 μm, the dielectric breakdown of a Si substrate is securely suppressed and dielectric strength specifications for HEV/EV power supplies can be satisfied without causing the Si substrate to be warped or cracked.

When tAlN/tT≧0.75, results below are obtained.

When a compound semiconductor multilayer structure has a thickness of about 0.9 μm to 2.3 μm, the dielectric breakdown of a Si substrate is securely suppressed and dielectric strength specifications for commercial power supplies can be satisfied without causing the Si substrate to be warped or cracked.

When a compound semiconductor multilayer structure has a thickness of about 1.5 μm to 2.3 μm, the dielectric breakdown of a Si substrate is securely suppressed and dielectric strength specifications for HEV/EV power supplies can be satisfied without causing the Si substrate to be warped or cracked.

When tAlN/tT≧0.84, results below are obtained.

When a compound semiconductor multilayer structure has a thickness of about 0.7 μm to 2.3 μm, the dielectric breakdown of a Si substrate is securely suppressed and dielectric strength specifications for commercial power supplies can be satisfied without causing the Si substrate to be warped or cracked.

When a compound semiconductor multilayer structure has a thickness of about 1.2 μm to 2.3 μm, the dielectric breakdown of a Si substrate is securely suppressed and dielectric strength specifications for HEV/EV power supplies can be satisfied without causing the Si substrate to be warped or cracked.

In this embodiment, since the AlGaN/GaN-HEMT includes the compound semiconductor multilayer structure 2 and the compound semiconductor multilayer structure 2 has excellent dielectric breakdown resistance as described above, the dielectric breakdown of the Si substrate 1 can be sufficiently suppressed and the AlGaN/GaN-HEMT has a very small leakage current when the AlGaN/GaN-HEMT is pinched off. Therefore, the AlGaN/GaN-HEMT has high reliability.

### Second Embodiment

This embodiment as well as the first embodiment discloses an AlGaN/GaN-HEMT useful as a compound semiconductor device. This second embodiment is different from the first embodiment in that a thick buffer layer made of AlGaN is formed instead of the first buffer layer 2A made of AlN. The same members as those described in the first embodiment are denoted by the same reference numerals as those used in the first embodiment and will not be described in detail.

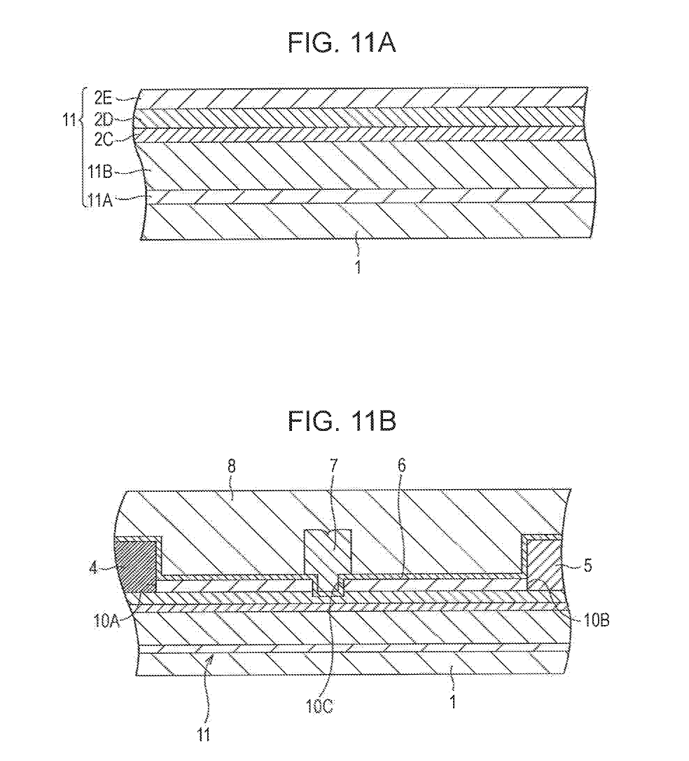

FIG. 11 is a schematic sectional view illustrating main steps of a method of manufacturing the AlGaN/GaN-HEMT according to the second embodiment.

As illustrated in FIG. 11A, a compound semiconductor multilayer structure 11 is formed on a Si substrate 1.

The compound semiconductor multilayer structure 11 includes a first buffer layer 11A, a second buffer layer 11B, an electron travel layer 2C, an electron supply layer 2D, and a cap layer 2E. The first buffer layer 11A is made of AlN. The second buffer layer 11B is made of i-AlGaN. The other layers are similar to those described in the first embodiment, that is, the electron travel layer 2C is made of i-GaN, the electron supply layer 2D is made of n-AlGaN, and the cap layer 2E is made of n-GaN.

In this embodiment, the compound semiconductor multilayer structure 11 has a thickness of about 10 μm or less and the percentage of Al atoms is 50% or more of the number of Group III element atoms contained therein. The compound semiconductor multilayer structure 2 contains a Group V element and Group III elements. The Group V element is N and the Group III elements are Ga and Al. N is chemically bonded to all of the Group III elements. Thus, the percentage of N atoms is theoretically 50% of the number of all atoms in the compound semiconductor multilayer structure 11. The percentage of Al atoms is 25% or more of the number of all atoms, that is, the percentage of the Al atoms is 50% or more of the number of all atoms of the Group III elements. In other words, this means that the number of Al—N bonds is 50% or more of the number of all chemical bonds (Ga—N bonds and Al—N bonds) of the Group III elements to N.

The first buffer layer 11A has a function of forming growth nuclei and a function of buffering the difference in lattice constant between Si in the Si substrate 1 and AlGaN in the second buffer layer 11B. The second buffer layer 11B has a function of buffering the difference in lattice constant between AlGaN in the second buffer layer 11B and GaN in the electron travel layer 2C and a function of resisting dielectric breakdown as described below.

In order to form the compound semiconductor multilayer structure 11, compound semiconductors below are deposited on the Si substrate 1 by a crystal growth process, for example, an MOCVD process. MBE or the like may be used instead of the MOCVD process.

AlN is deposited on the Si substrate 1 to a thickness of about 100 nm, whereby the first buffer layer 11A is formed.

In this operation, AlN is deposited in such a manner that a gas mixture of a TMAl gas and an NH₃ gas is used as a source gas and the V/III ratio is set to, for example, about 3,000.

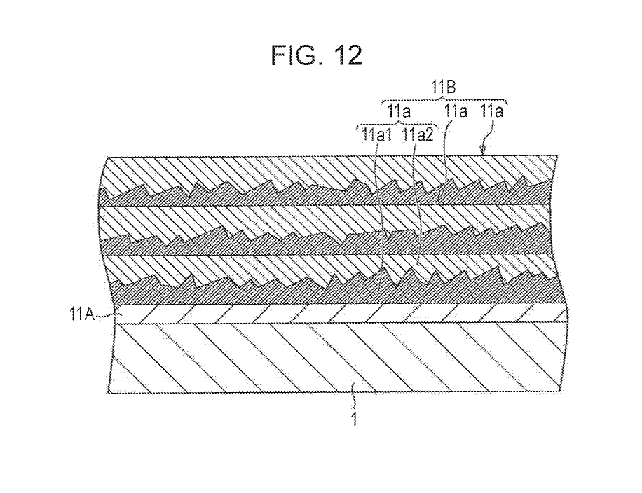

Next, i-AlGaN is thickly deposited on the first buffer layer 11A to a thickness of about 1,000 nm, whereby the second buffer layer 11B is formed. This operation is illustrated in FIGS. 11A and 12.

The compositional proportions of Al and Ga in i-AlGaN satisfy the inequality 0.7≦x<1 (herein x=0.7 (70%)), wherein x is the compositional proportion of Al (AlₓGa₁₋ₓN). When x is less than 0.7, it is difficult to achieve the percentage of the Al atoms in relation to the thickness of the second buffer layer 11B. When x is 0.7 or more, the percentage thereof can be securely achieved in relation to the thickness of the second buffer layer 11B.

In particular, a gas mixture of a TMAl gas, a TMGa gas, and an ammonia (NH₃) gas is used as a source gas. The ratio of NH₃ to TMAl or TMGa, that is, the V/III ratio is set to 10,000 or more, for example, 20,000. For example, 1-AlGaN is deposited to a thickness of about 50 nm, whereby a lower AlGaN layer 11a1 is formed. Since the lower AlGaN layer 11a1 is formed under such a condition that the ratio of NH₃ to TMAl or TMGa, that is, the V/III ratio is large as described above, i-AlGaN forms islands on a growth surface and therefore the lower AlGaN layer 11a1 has an hubbly surface.

Next, the ratio of NH₃ to TMAl or TMGa, that is, the V/III ratio is set to 2.0 or less, for example, 1.0 and i-AlGaN is deposited on the lower AlGaN layer 11a1 to a thickness of, for example, about 100 nm, whereby an upper AlGaN layer 11a2 is formed. Since the upper AlN layer 2a2 is formed under such a condition that the ratio of NH₃ to TMAl or TMGa, that is, the V/III ratio is very small as described above, the migration of Al atoms and N atoms on a growth surface is promoted and therefore the upper AlGaN layer 11a2 has a flat surface. The upper AlGaN layer 11a2 has an Al content (the percent of Al) larger than that of the lower AlGaN layer 11a1 because of the difference in the V/III ratio. The upper AlGaN layer 11a2 is deposited over the lower AlGaN layer 11a1 as described above, whereby an AlGaN layer 11a with a flat surface is formed.

A step of forming the AlGaN layer 11a is repeated several times, for example, seven times, whereby several AlGaN layers 11a (herein seven AlGaN layers 11a) are stacked to form the second buffer layer 11B. The second buffer layer 11B has a large thickness of about 1,000 nm. The upper AlGaN layer 11a2 is uppermost and therefore the second buffer layer 11B has a flat surface. For example, TEM analysis confirms that the AlGaN layers 11a making up the second buffer layer 11B each have a multilayer structure consisting of the lower AlGaN layer 11a1, which has the hubbly surface, and the upper AlGaN layer 11a2, which has the flat surface.

In this embodiment, in order to ensure the dielectric strength of a substrate by raising the content of Al in a compound semiconductor multilayer structure, an AlGaN buffer layer placed between the substrate and an electron travel layer is thickly formed. However, AlGaN is not lattice-matched to substrate materials such as Si and SIC. Therefore, if AlGaN is thickly deposited on the substrate, a large stress is caused in AlGaN because of lattice mismatch. Therefore, it is difficult to form a thick AlGaN layer.

In this embodiment, the lower AlGaN layers 11a1 and the upper AlGaN layers 11a2 have island-shaped growth surfaces and flat growth surfaces, respectively, and are alternately stacked to form the second buffer layer 11B. The second buffer layer 11B, which is substantially thick, is formed by alternately stacking the lower and upper AlGaN layers 11a1 and 11a2, which are different in surface morphology and are relatively thin, as described above, whereby the stress in the second buffer layer 11B is relieved. It has been found that a thick AlGaN crystal can be stably formed even if there is a large lattice mismatch between the substrate and AlGaN.

In order to alternately deposit the lower AlGaN layers 11a1, which have the island-shaped growth surfaces, and the upper AlGaN layers 11a2, which have the flat growth surfaces, a method other than a method of varying the V/III ratio may be used. For example, a method of varying the growth temperature of AlGaN can be used. In particular, the lower AlGaN layers 11a1 are grown at a temperature of, for example, about 850° C. to 950° C. and the upper AlGaN layers 11a2 may be grown at a temperature higher than the growth temperature of the lower AlGaN layers 11a1, that is, a temperature of, for example, about 1,000° C. to 1,150° C.

Subsequently to the formation of the second buffer layer 11B, the electron travel layer 2C, the electron supply layer 2D, and the cap layer 2E are deposited on the second buffer layer 11B in that order.

In particular, the electron travel layer 2C is formed in such a manner that i-GaN is thinly deposited on the second buffer layer 11B, which has a flat surface, to a thickness of, for example, about 100 nm. The electron supply layer 2D is formed in such a manner that n-AlGaN (Al_{0.25}Ga_{0.75}N) is deposited to a thickness of about 30 nm. The cap layer 2E is formed in such a manner that n-GaN is deposited to a thickness of about 10 nm.

The compound semiconductor multilayer structure 11 is formed on the Si substrate 1 as described above.

Steps illustrated in FIGS. 1B to 3B are performed in the same manner as that described in the first embodiment. Through the steps, a source electrode 4, a drain electrode 5, and a gate electrode 7 are covered with a passivation layer 8.

Wiring lines connected to the source electrode 4, the drain electrode 5, and the gate electrode 7 are formed; a protective layer is formed thereover; and connection electrodes exposed at the top are formed. Through these steps, the AlGaN/GaN-HEMT according to this embodiment is formed.

In this embodiment, the AlGaN/GaN-HEMT includes the gate insulating layer 6 as exemplified above and therefore is of a MIS type. The AlGaN/GaN-HEMT may be of a Schottky type, that is, the gate electrode 7 may be in direct contact with the compound semiconductor multilayer structure 11 without forming the gate insulating layer 6.

A gate-recess structure in which the gate electrode 7 is placed in an electrode recess 10C does not have to be used. That is, the gate insulating layer 6 and the gate electrode 7 may be formed on the compound semiconductor multilayer structure 11 in that order or the gate electrode 7 may be formed directly on the compound semiconductor multilayer structure 11 without forming any recess in the compound semiconductor multilayer structure 11.

In this embodiment, the percentage of AlGaN (this is, the percentage of Al—N chemical bonds therein) in the compound semiconductor multilayer structure 11 is set to be large under the restriction that the thickness of the compound semiconductor multilayer structure 11 is about 10 μm or less. In particular, the compound semiconductor multilayer structure 11 is formed such that the percentage of Al atoms is 25% or more of the number of all atoms contained in the compound semiconductor multilayer structure 11, that is, the percentage of the Al atoms is 50% or more of the number of all atoms of the Group III elements. In this embodiment, the second buffer layer 11B, which is made of AlGaN, is formed between the first buffer layer 11A and the electron travel layer 2C so as to have a large thickness and the electron travel layer 2C is formed so as to have a small thickness, whereby the requirement for the percentage of the Al atoms is achieved.

That is, the presence of the second buffer layer 11B, which is thick, allows the compound semiconductor multilayer structure 11 to have am increased content of Al—N bonds and increased dielectric breakdown resistance. On the other hand, the presence of the electron travel layer 2C, which is thin, allows the compound semiconductor multilayer structure 11 to have a reduced GaN content and reduces a stress in Si substrate due to the difference in lattice constant between GaN and the Si substrate 1. This is capable of securely suppressing the dielectric breakdown of the Si substrate 1 without warping or cracking the Si substrate 1.

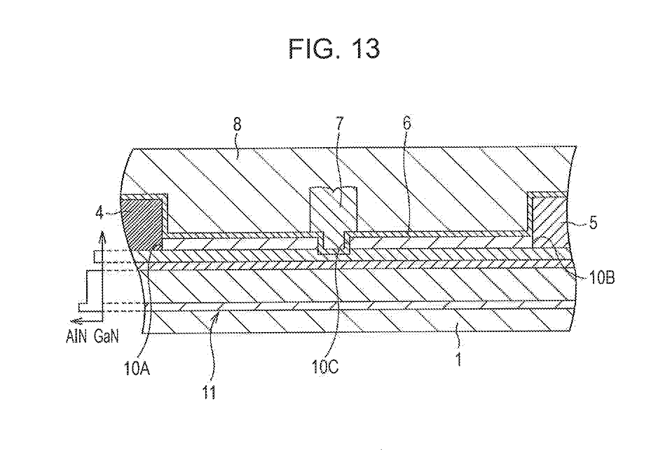

In particular, in the compound semiconductor multilayer structure 11, the second buffer layer 11B, which is made of AlGaN, is formed so as to have a large thickness of about 1,000 nm and the electron travel layer 2C, which is made of GaN, is formed so as to have a small thickness of about 100 nm as illustrated in FIG. 13, which includes a depthwise distribution map of components that is attached to the left side of FIG. 11B. This allows the percentage of the Al atoms to be 25% or more of the number of all atoms in the compound semiconductor multilayer structure 11.

In this embodiment as well as the first embodiment, the thickness of the second buffer layer 11B is determined in relation to the thickness of the compound semiconductor multilayer structure 11 in consideration of the impact on the Si substrate 1 and the dielectric strength desired for devices such that the percentage of Al atoms in the compound semiconductor multilayer structure 11 is within the above range. In this embodiment, the electron supply layer 2D and the cap layer 2E have a smaller thickness as compared with the other layers of the compound semiconductor multilayer structure 11 and therefore the change in thickness of the electron supply layer 2D and the cap layer 2E hardly contributes to the change in the percentage of the number of atoms of a Group III element. The first buffer layer 11A is used without being changed in thickness. Therefore, in the compound semiconductor multilayer structure 11, those greatly contributing to the change in the percentage of the number of the Group III element atoms through the change in thickness thereof are substantially two layers: the second buffer layer 11B and the electron travel layer 2C. Thus, determining the thickness of the second buffer layer 11B in relation to the thickness of the compound semiconductor multilayer structure 11 is substantially synonymous with determining the thickness of the second buffer layer 11B in relation to the thickness of the electron travel layer 2C.

Suppose that tT (μm) is the thickness of the compound semiconductor multilayer structure 11 and tAlGaN (μm) is the thickness of the second buffer layer 11B, which is made of i-AlGaN. In the case where the second buffer layer 11B, which is made of Al_{0.7}Ga_{0.3}N, is formed so as to have a thickness of about 1,000 nm and the electron travel layer 2C, which is made of GaN, is formed so as to have a thickness of about 100 nm as exemplified in this embodiment, when the ratio tAlGaN/tT is 0.5 or more, the requirement for the percentage of the Al atoms is satisfied.

In this embodiment as well as the first embodiment, the tAlGaN/tT can be determined in relation to the dielectric strength desired for commercial power supplies and the dielectric strength desired for HEV/EV power supplies.

In this embodiment, i-AlGaN is exemplified as a material for forming the second buffer layer 11B. However, for example, i-InAlN may be used instead of i-AlGaN. In this case, a thick layer of i-InAlN can be formed in such a manner that deposition in which the ratio of NH₃ to TMAl or TMIn, that is, the ratio is 10,000 or more and deposition in which the V/III ratio is 2 or less are repeatedly performed predetermined times.

In the first or second embodiment, in order to form a thick buffer layer, at least two selected from i-AlN, i-AlGaN, and i-InAlN may be appropriately deposited.

In this embodiment, since the AlGaN/GaN-HEMT includes the compound semiconductor multilayer structure 11 and the compound semiconductor multilayer structure 11 has excellent dielectric breakdown resistance as described above, the dielectric breakdown of the Si substrate 1 can be sufficiently suppressed and the AlGaN/GaN-HEMT has a very small leakage current when the AlGaN/GaN-HEMT is pinched off. Therefore, the AlGaN/GaN-HEMT has high reliability.

### Third Embodiment

This embodiment discloses a power supply unit using the AlGaN/GaN-HEMT according to the first or second embodiment.

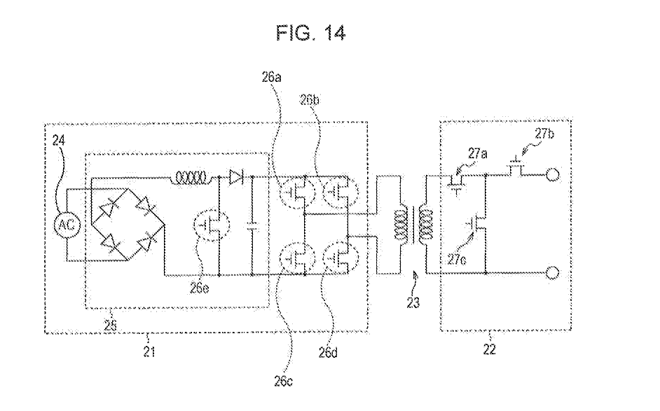

FIG. 14 is a wiring diagram illustrating the schematic configuration of the power supply unit according to the third embodiment.

The power supply unit according to this embodiment includes a high-voltage primary circuit 21, a low-voltage secondary circuit 22, and a transformer 23 placed between the primary circuit 21 and the secondary circuit 22.

The primary circuit 21 includes an alternating-current power supply 24, a so-called bridge rectifier circuit 25, and several (herein four) switching elements 26a, 26b, 26c, and 26d. The bridge rectifier circuit 25 includes a switching element 26e.

The secondary circuit 22 includes several (herein three) switching elements 27a, 27b, and 27c.

In this embodiment, the switching elements 26a, 26b, 26c, 26d and 26e of the primary circuit 21 each include an AlGaN/GaN-HEMT that is the same as that according to the first or second embodiment. The switching elements 27a, 27b, and 27c of the secondary circuit 22 each include a common MISFET containing silicon.

In this embodiment, the AlGaN/GaN-HEMTs are used in the primary circuit 21. The AlGaN/GaN-HEMTs each include a compound semiconductor multilayer structure having excellent dielectric breakdown resistance and a Si substrate 1. Therefore, the dielectric breakdown of the Si substrate 1 can be sufficiently suppressed and the AlGaN/GaN-HEMTs have a very small leakage current when the AlGaN/GaN-HEMTs are pinched off. This allows the power supply unit to have high reliability and high power.

### Fourth Embodiment

This embodiment discloses a high-frequency amplifier using the AlGaN/GaN-HEMT according to the first or second embodiment.

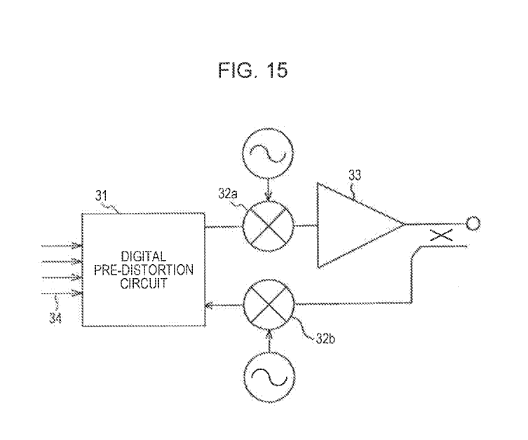

FIG. 15 is a wiring diagram illustrating the schematic configuration of the high-frequency amplifier according to the fourth embodiment.

The high-frequency amplifier according to this embodiment includes a digital pre-distortion circuit 31, mixers 32a and 32b, and a power amplifier 33.

The digital pre-distortion circuit 31 compensates for the non-linear distortion of an input signal 34. The mixer 32a mixes an alternating-current signal and the input signal 34 of which the non-linear distortion is compensated for. The power amplifier 33 amplifies the input signal 34 mixed with the alternating-current signal and includes the AlGaN/GaN-HEMT according to the first or second embodiment. With reference to FIG. 15, an output signal is mixed with the input signal 34 by the mixer 32b and can be transmitted to the digital pre-distortion circuit 31.

In this embodiment, the high-frequency amplifier includes the AlGaN/GaN-HEMT. The AlGaN/GaN-HEMT includes a compound semiconductor multilayer structure having excellent dielectric breakdown resistance and a Si substrate 1. Therefore, the dielectric breakdown of the Si substrate 1 can be sufficiently suppressed and the AlGaN/GaN-HEMT has a very small leakage current when the AlGaN/GaN-HEMT is pinched off. This allows the high-frequency amplifier to have high reliability.

### Other Embodiments

In the first to fourth embodiments, AlGaN/GaN-HEMTs have been exemplified as compound semiconductor devices. HEMTs other than the AlGaN/GaN-HEMTs can be used as compound semiconductor devices as described below.

First example of another type of HEMT

This example discloses an InAlN/GaN-HEMT useful as a compound semiconductor device.

InAlN and GaN are compound semiconductors of which the lattice constants can be brought close to each other depending on the compositions thereof. The InAlN/GaN-HEMT includes a compound semiconductor multilayer structure including an electron travel layer made of i-GaN, an electron supply layer made of n-InAlN, and a cap layer made of n-GaN. Piezoelectric polarization is hardly induced in the compound semiconductor multilayer structure and therefore a two-dimensional electron gas is generated principally by the spontaneous polarization of InAlN.

In the InAlN/GaN-HEMT of this example, the compound semiconductor multilayer structure includes buffer layers similar to those described in the first or second embodiment. In the case of using the buffer layers similar to those described in the first embodiment, a first buffer layer is formed from AlN so as to have a large thickness and a second buffer layer is formed from i-AlGaN. In the case of using the buffer layers similar to those described in the second embodiment, the first buffer layer is formed from AlN and the second buffer layer is formed from i-AlGaN so as to have a large thickness. In the case of using the buffer layers similar to those described in the second embodiment, for example, i-InAlN may be used to form the second buffer layer instead of i-AlGaN. In the case of using the buffer layers similar to those described in the first or second embodiment, thick buffer layers may be formed by depositing at least two selected from i-AlN, i-AlGaN, and i-InAlN.

According to this example, since the InAlN/GaN-HEMT includes the compound semiconductor multilayer structure, which has excellent dielectric breakdown resistance, the dielectric breakdown of a Si substrate 1 can be sufficiently suppressed and the InAlN/GaN-HEMT has a very small leakage current when the InAlN/GaN-HEMT is pinched off. Therefore, the InAlN/GaN-HEMT as well as the AlGaN/GaN-HEMTs has high reliability.

Second example of another type of HEMT

This example discloses an InAlGaN/GaN-HEMT useful as a compound semiconductor device.

GaN and InAlGaN are compound semiconductors and the lattice constants of InAlGaN can be reduced to less than those of GaN depending on the compositions thereof. The InAlGaN/GaN-HEMT includes a compound semiconductor multilayer structure including an electron travel layer made of GaN, an electron supply layer made of n-InAlGaN, and a cap layer made of n-GaN.

In the InAlGaN/GaN-HEMT of this example, the compound semiconductor multilayer structure includes buffer layers similar to those described in the first or second embodiment. In the case of using the buffer layers similar to those described in the first embodiment, a first buffer layer is formed from AlN so as to have a large thickness and a second buffer layer is formed from i-AlGaN. In the case of using the buffer layers similar to those described in the second embodiment, the first buffer layer is formed from AlN and the second buffer layer is formed from i-AlGaN so as to have a large thickness. In the case of using the buffer layers similar to those described in the second embodiment, for example, i-InAlN may be used to form the second buffer layer instead of i-AlGaN. In the case of using the buffer layers similar to those described in the first or second embodiment, thick buffer layers may be formed by depositing at least two selected from i-AlN, i-AlGaN, and i-InAlN.

According to this example, since the InAlGaN/GaN-HEMT includes the compound semiconductor multilayer structure, which has excellent dielectric breakdown resistance, the dielectric breakdown of a Si substrate 1 can be sufficiently suppressed and the InAlGaN/GaN-HEMT has a very small leakage current when the InAlGaN/GaN-HEMT is pinched off. Therefore, the InAlGaN/GaN-HEMT as well as the AlGaN/GaN-HEMTs has high reliability.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A compound semiconductor device comprising:
a substrate; and
a compound semiconductor multilayer structure which is formed above the substrate and which contains compound semiconductors containing Group III elements,
wherein the compound semiconductor multilayer structure has a thickness of 10 μm or less and a percentage of aluminum atoms is 50% or more of number of atoms of the Group III elements.

2. The compound semiconductor device according to claim 1,
wherein the compound semiconductor multilayer structure includes a buffer layer containing aluminum and a ratio of a thickness of the buffer layer to the thickness of the compound semiconductor multilayer structure is 0.5 or more.

3. The compound semiconductor device according to claim 2,
wherein the compound semiconductor multilayer structure has a thickness of 1.3 μm to 2.3 μm.

4. The compound semiconductor device according to claim 2,
wherein the ratio of the thickness of the buffer layer to the thickness of the compound semiconductor multilayer structure is 0.75 or more.

5. The compound semiconductor device according to claim 4,
wherein the compound semiconductor multilayer structure has a thickness of 0.9 μm to 2.3 μm.

6. The compound semiconductor device according to claims 2,
wherein the buffer layer includes first sub-layers each having an hubbly surface and second sub-layers each having a flat surface, the first and second sub-layers are alternately stacked, and one of the second sub-layers is uppermost.

7. The compound semiconductor device according to claims 2,
wherein the buffer layer is made of at least one selected from a group consisting of AlN, AlGaN, and InAlN.

8. The compound semiconductor device according to claims 1,
wherein the compound semiconductor multilayer structure includes an electron travel layer containing GaN and the electron travel layer has a thickness of 250 nm or less.

9. A compound semiconductor device comprising:
a substrate;
a buffer layer that is formed above the substrate; and
a compound semiconductor multilayer structure that is formed above the buffer layer,
wherein the buffer layer includes first buffer sub-layers that have hubbly surfaces and contain aluminum and also includes second buffer sub-layers that cover the hubbly surfaces and contain aluminum, an aluminum content of the second buffer sub-layers is greater than an aluminum content of the first buffer sub-layers, and the first and second buffer sub-layers are alternately stacked, and one of the second sub-layers is uppermost.

10. A method of manufacturing a compound semiconductor device including a substrate and a compound semiconductor multilayer structure which is formed above the substrate and which contains compound semiconductors containing Group III elements, the method comprising:
forming the compound semiconductor multilayer structure such that the compound semiconductor multilayer structure has a thickness of 10 μm or less and a percentage of aluminum atoms is 50% or more of number of atoms of the Group III elements.

11. The method according to claim 10,
wherein the compound semiconductor multilayer structure includes a buffer layer containing aluminum and the ratio of a thickness of the buffer layer to the thickness of the compound semiconductor multilayer structure is 0.5 or more.

12. The method according to claim 11,
wherein the compound semiconductor multilayer structure has a thickness of 13 μm to 2.3 μm.

13. The method according to claim 11,
wherein the ratio of the thickness of the buffer layer to the thickness of the compound semiconductor multilayer structure is 0.75 or more.

14. The method according to claim 13,
wherein the compound semiconductor multilayer structure has a thickness of 0.9 μm to 2.3 μm.

15. The method according to claim 11,
wherein the buffer layer includes first sub-layers each having an hubbly surface and second sub-layers each having a flat surface, the first and second sub-layers are alternately stacked, and one of the second sub-layers is uppermost.

16. The method according to claim 15,
wherein the first and second sub-layers are formed by a crystal growth process, the first sub-layers are each formed on a corresponding one of the second sub-layers at a first ratio defined as a ratio of a Group V element source material to a Group III element source material, and the second sub-layers are formed at a second ratio which is defined as the ratio of the Group V element source material to the Group III element source material and which is less than the first ratio.

17. The method according to claim 16,
wherein the first ratio is 10,000 or more and the second ratio is 2.0 or less.

18. The method according to any one of claim 11,
wherein the buffer layer is formed from at least one selected from the group consisting of AlN, AlGaN, and InAlN.

19. The method according to claims 10,
wherein the compound semiconductor multilayer structure includes an electron travel layer containing GaN and the electron travel layer has a thickness of 250 nm or less.

20. A power supply unit comprising:
a high-voltage circuit;
a low-voltage circuit; and
a transformer that is placed between the high-voltage circuit and the low-voltage circuit,
wherein the high-voltage circuit includes a transistor, the transistor includes a substrate and a compound semiconductor multilayer structure which is formed above the substrate and which contains compound semiconductors containing Group III elements, the compound semiconductor multilayer structure has a thickness of 10 μm or less, and a percentage of aluminum atoms is 50% or more of the number of atoms of the Group III elements.

21. A high-frequency amplifier amplifying an input high-frequency voltage to output an amplified high-frequency voltage, comprising a transistor, wherein the transistor includes a substrate and a compound semiconductor multilayer structure which is formed above the substrate and which contains compound semiconductors containing Group III elements, the compound semiconductor multilayer structure has a thickness of 10 μm or less, and a percentage of aluminum atoms is 50% or more of the number of atoms of the Group III elements.

22. A compound semiconductor device comprising:
a substrate; and
a compound semiconductor multilayer structure which is formed above the substrate and which contains compound semiconductor layers made of III-V nitride compound semiconductor material,
wherein the compound semiconductor multilayer structure has a thickness of 10 μm or less and a percentage of aluminum atoms in the compound semiconductor multilayer structure being 50% or more of number of atoms of Group III elements in the compound semiconductor multilayer structure.
